(19) United States
(12) Patent Application Publication
(10) Pub. No.: US 2013/0199827 A1
(43) Pub. Date: Aug. 8, 2013

(54) Mounting Board and Circuit Device Using the Same

(71) Applicants: Yusuke Igarashi, Isesaki-shi (JP); Atsushi Kato, Kiryu-shi (JP); Toshimichi Naruse, Oizumi-machi (JP)

(72) Inventors: Yusuke Igarashi, Isesaki-shi (JP); Atsushi Kato, Kiryu-shi (JP); Toshimichi Naruse, Oizumi-machi (JP)

(73) Assignee: Sanyo Electric Co., Ltd., Osaka (JP)

(21) Appl. No.: 13/571,072

(22) Filed: Aug. 9, 2012

(30) Foreign Application Priority Data
Aug. 12, 2011 (JP) 2011-176805
Mar. 28, 2012 (JP) 2012-073467
Mar. 28, 2012 (JP) 2012-073468

(51) Int. Cl. H05K 1/02

(52) U.S. Cl. CPC H05K 1/0213
USPC 174/255

(57) ABSTRACT

A mounting board includes: a core layer made of an insulating resin; a first conductive pattern provided on a front side of the core layer; a second conductive pattern provided on a back side of the core layer; and a via provided between a first electrode for a high current in the first conductive pattern and an external electrode including the second conductive pattern, the external electrode provided so as to correspond to the first electrode, the first conductive pattern and the second conductive pattern having the same film thickness, the via set at a resistance value lower than a resistance value of the first conductive pattern so that the high current flows to the external electrode through the via.

### CROSS-REFERENCE TO RELATED APPLICATIONS

This application claims the benefit of priority to Japanese Patent Application Nos. 2011-176805, 2012-073467 and 2012-073468, filed Aug. 12, 2011, Mar. 28, 2012 and Mar. 28, 2012, respectively, of which full contents are incorporated herein by reference.

### BACKGROUND OF THE INVENTION

1. Field of the Invention

The present invention relates to a mounting board and a circuit device using the mounting board.

2. Description of the Related Art

Recently, electronic devices have become readily available and it has been becoming possible to obtain various kinds of information by simply taking the devices out of pockets or bags. One of the reasons for that is the reduction in size and weight of mobile devices. Mobile phones of the name-card size or smartphones having the size of approximately two name cards have been developed, allowing information processing possible anywhere in the world.

There are various factors having realized this reduction in size and weight, and the first factor is sophistication of IC. Various functions are incorporated in an IC chip and further the size thereof has been reduced. This small-sized IC chip has more terminals, and the sizes of the terminals are also reduced.

The second factor is an interposer for mounting this IC chip. This interposer is inserted between a set board and an IC chip and reduces a difference in a thermal expansion coefficient α between the IC chip and a set board.

This interposer (hereinafter referred to as a mounting board) has an insulating resin as a base, and granulated fillers such as oxidized Si, oxidized Al and the like or fibrous filler such as glass, carbon and the like are kneaded therein for adjustment of α.

FIG. 6 illustrates a mounting board 10. As an example, a two-layered board is illustrated, and reference numeral 11 denotes a core layer made of an insulating resin where a conductive pattern is provided on the front surface and back surface of this core layer 11. A first conductive pattern 12 is provided on the front side of the core layer 11, while a second conductive pattern 13 is provided on the back side. This first conductive pattern 12 is formed of an island for mounting a chip, a bonding pad or wiring and the like, while on the second conductive pattern 13, an electrode pad for a solder ball is provided for connection with a set board (See Japanese Laid-Open Patent Publication No. H01-266786).

Recently, with sophistication of functions of the mounting board 10, a thin conductive pattern 12A for a low current and a thick conductive pattern 12B for a high current have been becoming necessary for this mounting board. In the above-described Patent Literature, conductive patterns are applied to a metal board, and a thick conductive pattern and a thin conductive pattern are realized by two processes of etching.

For example, an inverter module or the like has a transistor 14 through which a high current flows and a control IC 15 for controlling this transistor 14 as illustrated in FIG. 6. This transistor 14 requires the thick conductive pattern 12B since a high current flows therethrough, while the control IC 15 requires the thin conductive pattern 12A since it does not require such a high current.

However, providing conductive patterns having different thicknesses on this mounting board 10 has a problem of increasing the number of manufacturing processes as described above. That is, a Cu foil having a thick film needs to be prepared in advance and a great film thickness and a small film thickness need to be prepared by performing two processes of etching.

As an alternative method, the conductive pattern 12A for a low current may have the same film thickness as that of the thick conductive pattern 12B without being reduced in thickness thereof. However, in this case, the following problems remain.

In general, a Cu pattern is realized by wet etching in view of a cost. Thus, the pattern is subjected to etching isotropically, and thus, such a problem is caused in the case of a thick Cu pattern that etching in the lateral direction progresses accordingly, thereby being unable to form a fine pattern. That is, if etching is executed for a thin conductive pattern, a fine pattern can be arranged with high density accordingly, but using this thick conductive pattern instead results in commensurate sacrifice in pattern.

FIGS. 7A and 7B illustrate a mounting board 20 including a four-layered conductive pattern. Assuming that a conductive pattern 21A on the outermost surface on the front surface side is 70 μm, for example, since the film thickness is great as described above, L/S is approximately 140 to 150 μm. However, in recent years, a flip-chip mounting is preferred for the control IC from the viewpoint of noise and a processing speed. That is because, in the flip-chip mounting, a metal thin wire is not needed, thereby being able to reduce the wiring length through which a signal flows.

Increase in the number of terminals and high terminal density in this flip-chip mounting requires L/S of approximately 100 μm in recent years. Thus, if a Cu foil having a film thickness of 70 μm is used, the L/S of 100 μm cannot be realized due to the great film thickness, resulting in difficulty performing flip-chip mounting.

Thus, if the conductive pattern 21A is to be realized with a copper foil (50 μm, for example) having a film thickness smaller than 70 μm, then a high current flowing from a power transistor 14 cannot be allowed to flow therein. Thus, a high current was passed through a via 22 as illustrated in FIG. 7A. However, in this case, the via 22 was drilled in the mounting board 20 and the via 22 was plated and filled. But, since a working process such as drilling or the like was added, an electrode 22A immediately above the via was irregular, resulting in difficulty in bonding.

Thus, a conductive pattern 22B formed on a flat portion of the mounting board 20 was subjected to wire bonding avoiding a spot immediately above the via 22 as in FIG. 7B.

However, the conductive pattern 22B here is a 50-μm copper foil and has a resistance, and passing the current of the transistor 14 causes a problem of fusing of the conductive pattern or temperature rise of the mounting board 20 itself.

### SUMMARY OF THE INVENTION

A mounting board according to an aspect of the present invention, includes: a core layer made of an insulating resin; a first conductive pattern provided on a front side of the core layer; a second conductive pattern provided on a back side of the core layer; and a via provided between a first electrode for a high current in the first conductive pattern and an external electrode including the second conductive pattern, the external electrode provided so as to correspond to the first electrode, the first conductive pattern and the second conductive pattern having the same film thickness, the via set at a resistance value lower than a resistance value of the first conductive pattern so that the high current flows to the external electrode through the via.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1A is a diagram illustrating a mounting board or a circuit device according to an embodiment of the present invention;

FIG. 1B is a diagram illustrating a mounting board or a circuit device according to an embodiment of the present invention;

FIG. 1C is a diagram illustrating a mounting board or a circuit device according to an embodiment of the present invention;

FIG. 1D is a diagram illustrating a mounting board or a circuit device according to an embodiment of the present invention;

FIG. 1E is a diagram illustrating a mounting board or a circuit device according to an embodiment of the present invention;

FIG. 2A is a diagram illustrating a manufacturing method of a circuit device according to an embodiment of the present invention;

FIG. 2B is a diagram illustrating a manufacturing method of a circuit device according to an embodiment of the present invention;

FIG. 2C is a diagram illustrating a manufacturing method of a circuit device according to an embodiment of the present invention;

FIG. 2D is a diagram illustrating a manufacturing method of a circuit device according to an embodiment of the present invention;

FIG. 3A is a diagram illustrating a manufacturing method of a circuit device according to an embodiment of the present invention;

FIG. 3B is a diagram illustrating a manufacturing method of a circuit device according to an embodiment of the present invention;

FIG. 3C is a diagram illustrating a manufacturing method of a circuit device according to an embodiment of the present invention;

FIG. 3D is a diagram illustrating a manufacturing method of a circuit device according to an embodiment of the present invention;

FIG. 4A is a diagram illustrating a manufacturing method of a circuit device according to an embodiment of the present invention;

FIG. 4B is a diagram illustrating a manufacturing method of a circuit device according to an embodiment of the present invention;

FIG. 4C is a diagram illustrating a manufacturing method of a circuit device according to an embodiment of the present invention;

FIG. 5A is a diagram illustrating a manufacturing method of a circuit device according to an embodiment of the present invention;

FIG. 5B is a diagram illustrating a manufacturing method of a circuit device according to an embodiment of the present invention;

FIG. 6 is a diagram illustrating a mounting board or a circuit device;

FIG. 7A is a diagram illustrating a mounting board or a circuit device;

FIG. 7B is a diagram illustrating a mounting board or a circuit device;

FIG. 8A is a diagram illustrating a circuit device according to an embodiment of the present invention;

FIG. 8B is a diagram illustrating a circuit device according to an embodiment of the present invention;

FIG. 9A is a diagram illustrating a circuit device according to an embodiment of the present invention;

FIG. 9B is a diagram illustrating a circuit device according to an embodiment of the present invention;

FIG. 10A is a diagram illustrating a manufacturing method of a circuit device according to an embodiment of the present invention;

FIG. 10B is a diagram illustrating a manufacturing method of a circuit device according to an embodiment of the present invention;

FIG. 10C is a diagram illustrating a manufacturing method of a circuit device according to an embodiment of the present invention;

FIG. 10D is a diagram illustrating a manufacturing method of a circuit device according to an embodiment of the present invention;

FIG. 11A is a diagram illustrating a manufacturing method of a circuit device according to an embodiment of the present invention;

FIG. 11B is a diagram illustrating a manufacturing method of a circuit device according to an embodiment of the present invention;

FIG. 11C is a diagram illustrating a manufacturing method of a circuit device according to an embodiment of the present invention;

FIG. 12 is a diagram illustrating a manufacturing method of a circuit device according to an embodiment of the present invention;

FIG. 13A is a diagram of a circuit device according to an embodiment of the present invention mounted on a metal board;

FIG. 13B is a diagram of a circuit device according to an embodiment of the present invention mounted on a metal board;

FIG. 14A is a diagram of a circuit device according to an embodiment of the present invention mounted on a set board;

FIG. 14B is a diagram of a circuit device according to an embodiment of the present invention mounted on a set board; and

FIG. 15 is a diagram illustrating a mounting board according to an embodiment of the present invention.

### DETAILED DESCRIPTION OF THE INVENTION

At least the following details will become apparent from descriptions of this specification and of the accompanying drawings.

An embodiment of the present invention will be described below.

In an embodiment of the present invention, terms of a mounting board and a circuit device are employed. Here, the circuit device employs a mounting board according to an embodiment of the present invention. If a semiconductor device and a passive device are employed, a hybrid integrated circuit device is configured. However, when only a semiconductor device is mounted on a mounting board, a semiconductor device is configured. If an LED is mounted thereon, a light emitting device or an illuminating device is configured, and further, if a power transistor and its control IC are mounted thereon and an inverter module is configured, which is a power module. Here, they are collectively referred to as a circuit device. Moreover, those in which this circuit device is mounted on a metal board, a printed board, a ceramic board and the like are referred to as board modules.

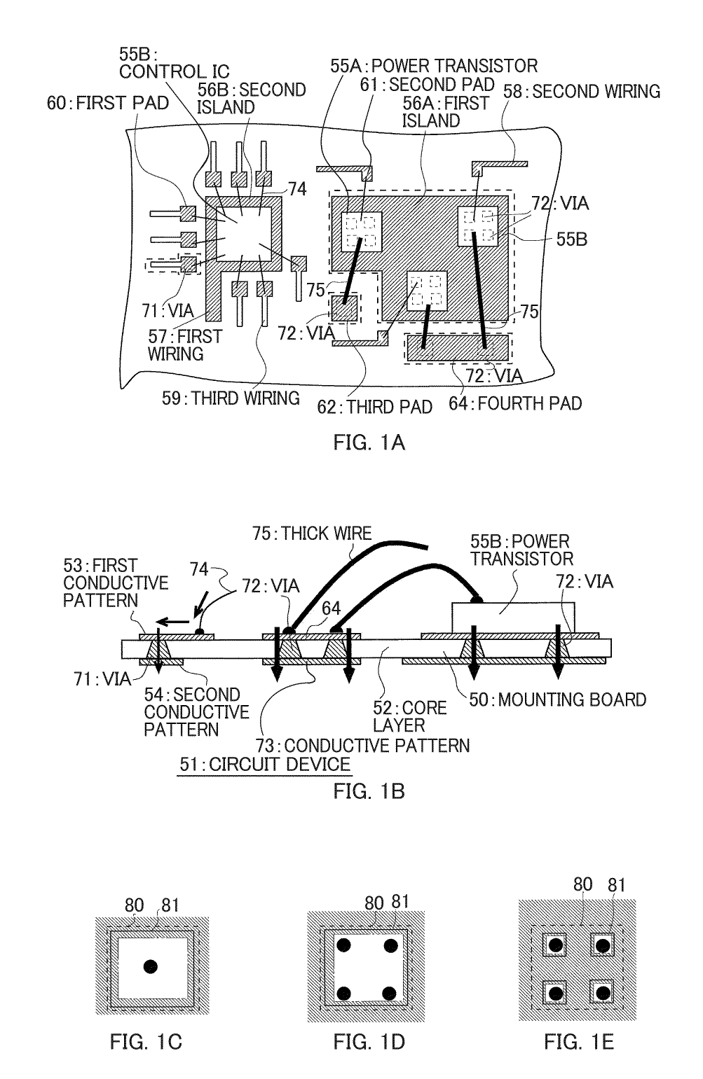

A mounting board 50 made of a two-layered board in FIG. 1 and a circuit device 51 employing the mounting board 50 will be described. Solid lines indicate a first conductive pattern 53 on the front side, bold dotted lines indicate a second conductive pattern on the back side, and thin dotted lines indicate the via.

First, a core layer 52 of this mounting board 50 is made of an insulating resin and made of a thermosetting or thermoplastic resin. As an example, it is made of polyimide or epoxy resins and the like, and a filler is mixed in these resins as described in examples. The filler is granular, crushed or fibrous, and is made of oxidized Si, oxidized Al, glass or the like. Here, a glass epoxy resin is employed in which a glass fiber is woven in an epoxy resin, and the thickness thereof is approximately 100 μm. A carbon fiber may be woven therein. These are mixed in order to reduce a difference in a thermal expansion coefficient α between a set board and a semiconductor device to be mounted.

A mounting board in which a metal layer is embedded may be employed as the core layer 52, which will be described last.

Subsequently, a conductive pattern will be described. The first conductive pattern 53 on the front side and the second conductive pattern 54 on the back side have a film thickness of approximately 30 to 50 μm, and are made of Cu or metal mainly composed of Cu or an alloy mainly composed of Cu and the like. Methods maybe forming the pattern on the mounting board by plating, or preparing a Cu foil made of these materials in advance and bonding it to the mounting board. Here, a bonding type Cu foil may be one grown by plating, or rolled Cu formed by rolling a plated film.

The first conductive pattern 53 on the front surface of the mounting board 50 is formed as a pattern as illustrated in FIG. 1A. Specifically, included therein are: first and second islands 56A and 56B on which semiconductor devices, e.g., a power transistor 55A and a control IC 55B configured to control it in an embodiment, are mounted; first, second, and third wirings 57, 58, and 59 for a low current; first and second pads 60 and 61 for a low current; third and fourth pads 62 and 64 for a high current; and the like. Wiring includes singular island-state wiring (omitted in the figures), those integrated with the island as indicated by reference numeral 57, and those integrated with the pad as indicated by reference numeral 59.

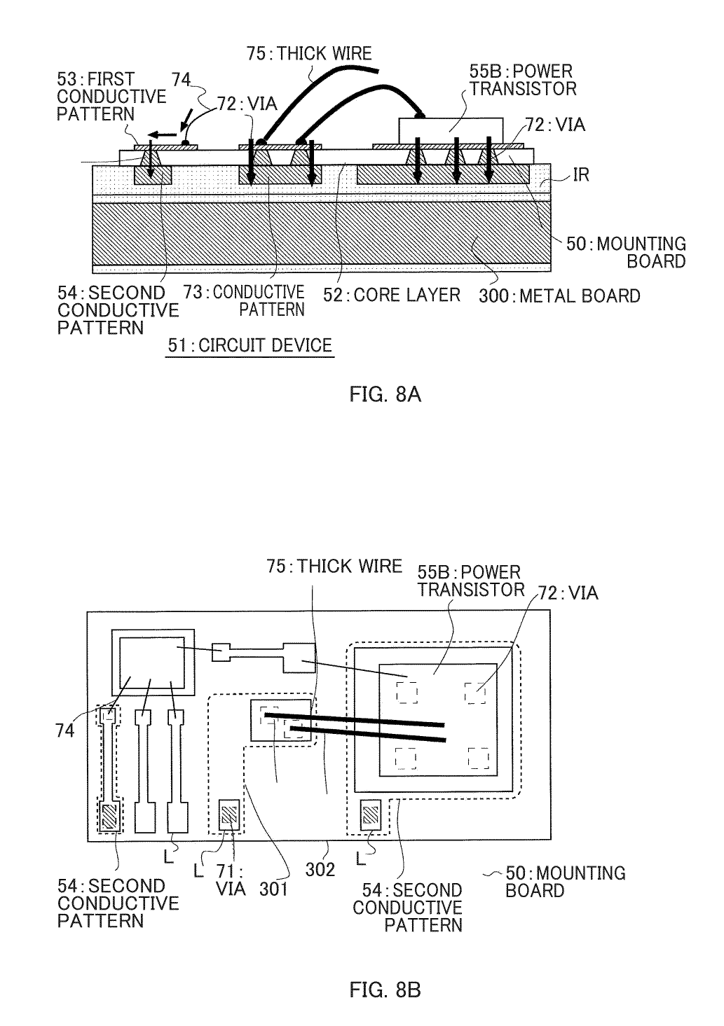

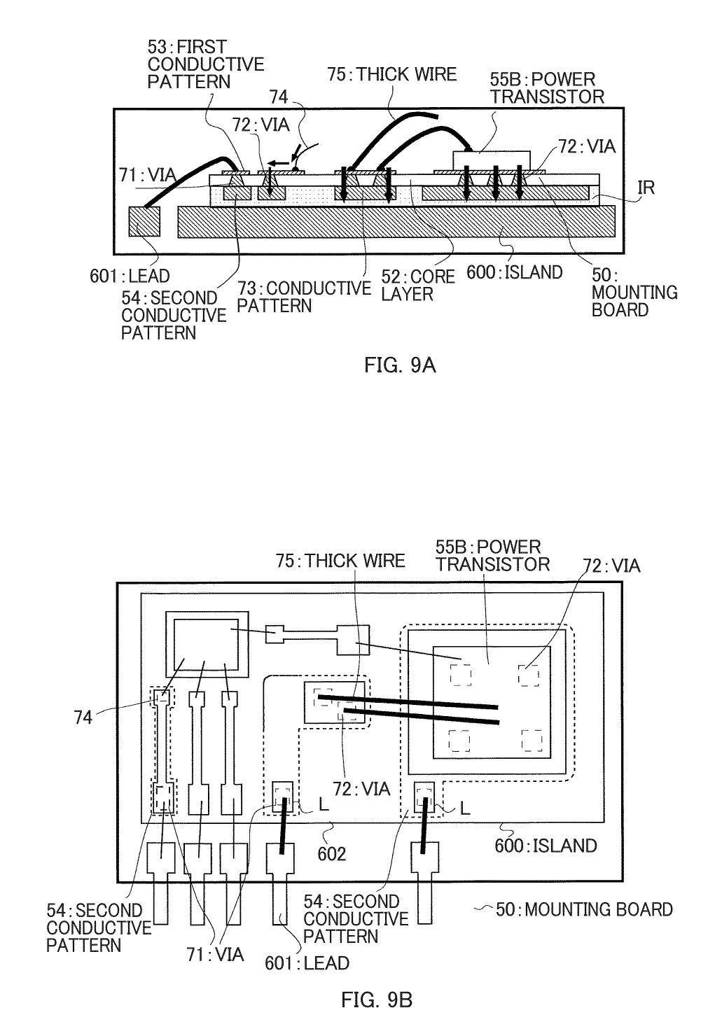

Moreover, the second conductive pattern 54 on the back side is made of an external electrode on which a brazing material such as solder is provided, wiring, and the like. The external electrode has a solder placed thereon by screen printing or a solder ball placed thereon to be heated and melted. A conductive paste such as an Ag paste may be provided instead of the solder. The wiring is not usually essential on the back side and may be provided as necessary such as when there is insufficient space on the front surface side or the like. In FIGS. 8 and 9, the wiring is provided thereon actively since a high current is passed on the back side of the mounting board.

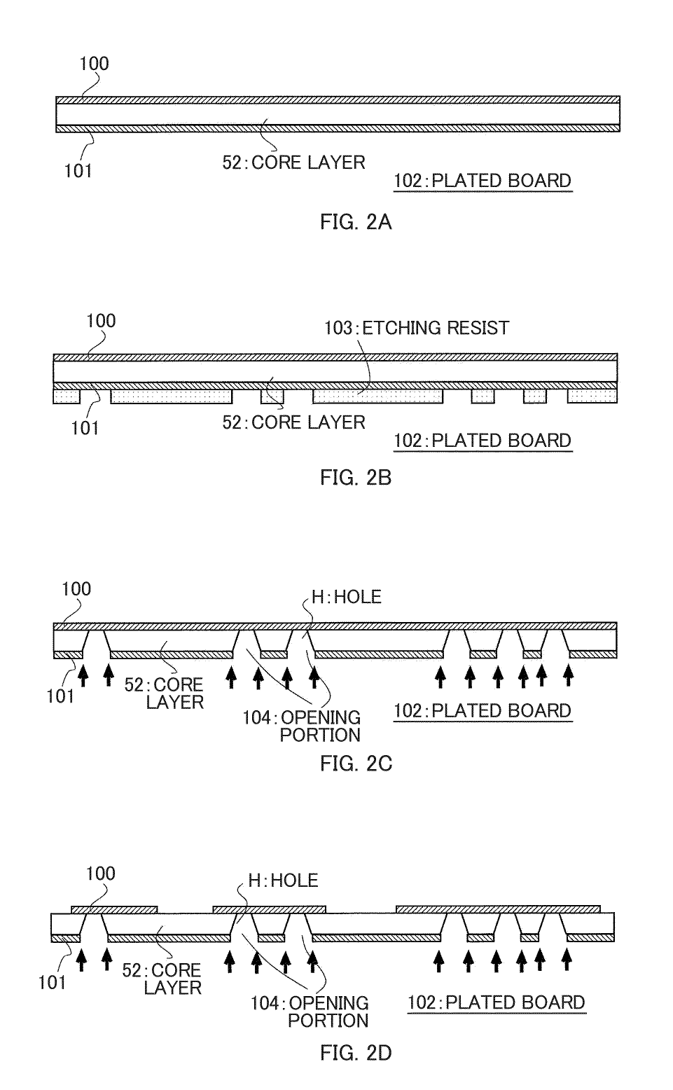

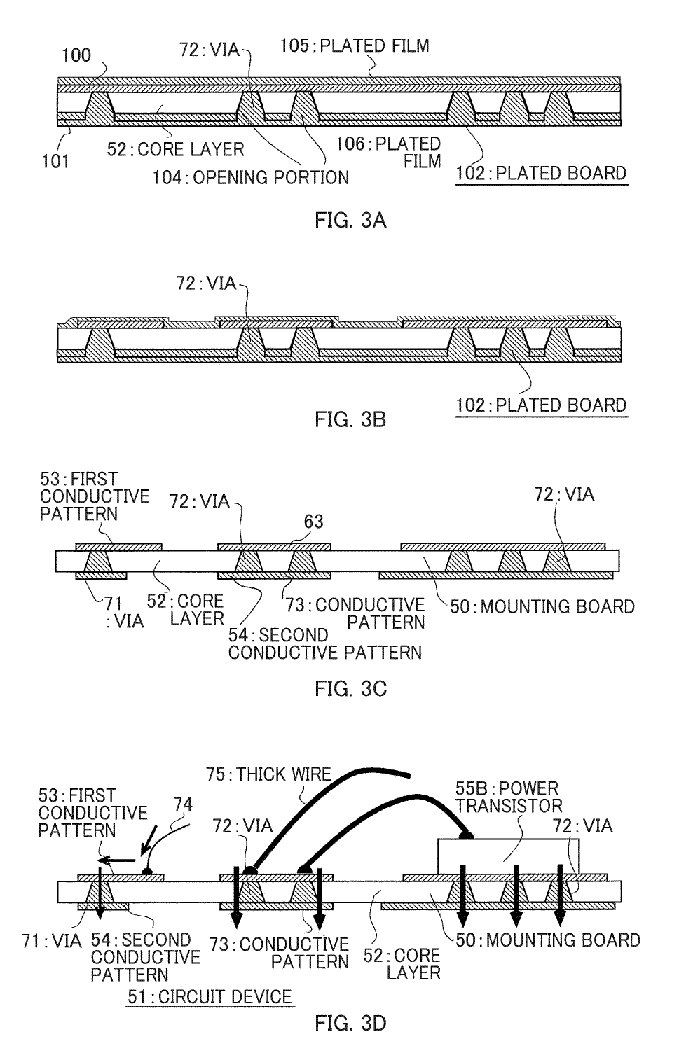

Furthermore, as illustrated in FIG. 1B, vias 71 and 72 are provided so as to penetrate the insulating board 50. The via is filled with plating (there may be some space for an unfilled portion in the inside or on the lower side of the via) or filled with a solder or a conductive paste. A point to be emphasized is that the first conductive pattern on the front surface side is flat so that flatness of the mounting board is traced. As illustrated in FIGS. 2 and 3, an opening portion OP is provided in the second conductive pattern on the back side so that the plating, conductive paste, solder or the like is filled therein, and no working process that might roughen the surface is applied on the first conductive pattern on the front side, and thus, the conductive pattern remains in a plated state or a bonded flat state, and flatness is maintained, which will be described later.

Points of an embodiment of the present invention will be described below.

First, the first conductive pattern 53 provided on the front surface side of the mounting board 50 has the same film thickness over the entire surface, and specifically, is configure with a thin conductive pattern for a low current, which has a film thickness of 40 to 50 μm here. The low current flows at least through the thin first conductive pattern 53. However, the current may flow to the second conductive pattern on the back side through the via as necessary. A high current flows by a route through the conductive pattern immediately above the via, the via, and the conductive pattern immediately below the via.

Specific description will be given referring to FIG. 1B. A metal thin wire 74 made of a thin wire connected to the control IC 55B is connected to the right end (e.g., the first pad 60 here) of the first conductive pattern 53 on the left side, and a low current here flows to the left side direction through the first conductive pattern 53. Though not shown here, the first conductive pattern 53 connected to the thin wire 74 is electrically connected to another circuit device through wiring on the front surface, and the first conductive pattern 53 is connected to an external electrode on the back surface through the via. The current may flow along an arrow through the first conductive pattern 53, and flow to the second conductive pattern 54 through the via 70 along the way. Since the current or signal of this low current is small, there is no problem caused even if the current flows to the thin conductive pattern on the front or back surface.

On the other hand, this is not the case for the high current. This is because both the first conductive pattern 53 and the second conductive pattern 54 have a small film thickness. The reason for this, which has been described before, is because the conductive pattern on the front surface side is to be made fine, thereby realizing high density. For example, if the number of IC pins is as large as 1000 pins or more, terminals are small, many wirings provided on the mounting board side might be crossed over when wire bonding is executed from the pad of the control IC. But if the film thickness is great, the spacing is widened, thereby requiring the length of the bonding wire. Since the recently developed control ICs are formed finer due to a technical progress, it is indispensable for the first conductive pattern 53 on the mounting board to be fine.

However, there may be two cases for this high current, which are flowing out of the power transistor 55A and flowing into the power transistor 55A. For example, the high current flows out to the pads 62 and 64 for a high current from the chip surface through the metal thin wire 75, as indicated by the bold line. Since the via 72 is provided, the current does not flow to the wiring on the front surface but flows to the back surface through the via 72. Here, the fourth pad 64 ensures an area whereto thick two wires can be connected, but pads may be separated corresponding to the respective wires. Reference numeral 61 denotes the second pad connected to a gate with a thin line, while reference numeral 58 denotes wiring integrated with this second pad 61.

The current flows from a conductive pattern 73 through the via 72 and the thick wire 75 to the power transistor 55B. In either case, the resistance of the via is filled with a conductive material and lower than the resistance of the first conductive pattern 53 or the second conductive pattern 54, and thus if the metal thin wire is connected immediately above the via, the high current flows through the via 72 without fail.

Subsequently, the first island 56A will be described. Here, this is a portion where a current flows out of the back surface of the power transistor 55A and/or flows into the back surface of the transistor. Thus, at least one via 72 is provided in a region of an island corresponding to the back surface of the power transistor 55A. In FIG. 1A, four vias are formed for one transistor 55A. Since the chip back surface is connected in common, three transistors 55A are provided for one island 56A.

However, it is only necessary that at least one transistor is provided on one island, at least one via is formed between the island on the front surface and a conductive pattern on the back surface, and a power transistor is fixed immediately above the via. For example, in FIGS. 1C to 1D, the second conductive pattern is seen from the back side of the mounting board 50. A shaded hatched area is solder resist. The dotted line indicates an island 80 on the front surface side of the mounting board 50, for example, and the single power transistor 55B, though not shown, is electrically connected and fixed thereto. The solid line indicates a back surface electrode 81 provided on the back surface of the insulating board 50.

That is, in FIG. 1C, for one power transistor, there are one via, one back surface electrode, and one solder fixing area, and the power transistor is fixed immediately above the via. In FIG. 1D, for one power transistor, there are four vias, one back surface electrode, and one solder fixing area, and the power transistor is provided above the four vias. In FIG. 1E, for one power transistor, there are four vias, four back surface electrodes respectively corresponding to four vias, and four solder fixing areas. As such, the back surface electrode is formed with flexibility.

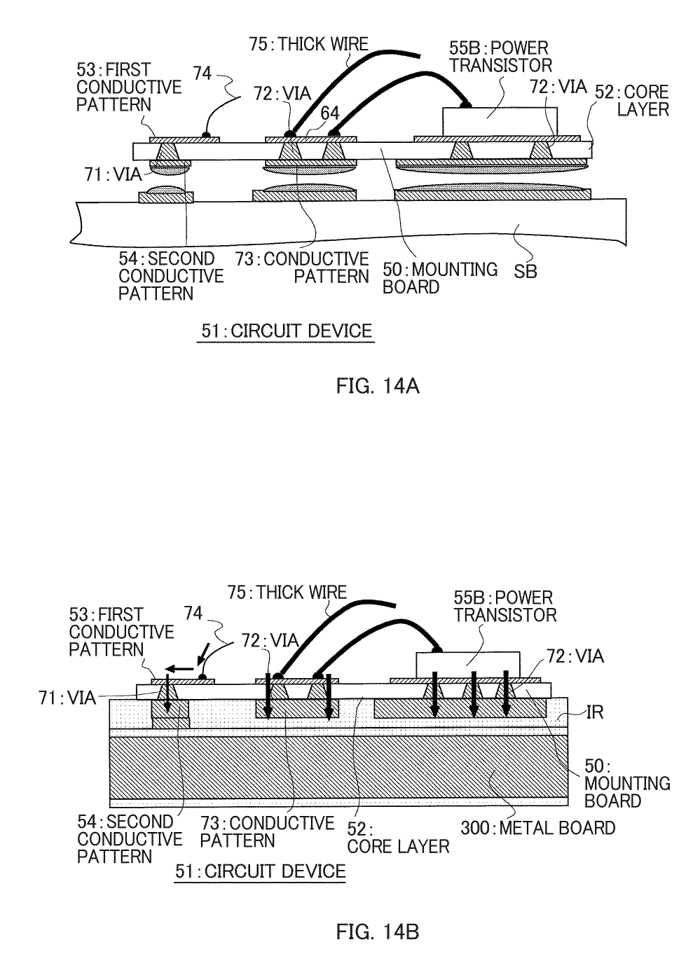

Though roughly illustrated in FIG. 1, since the first conductive pattern 53 on the front surface has a small film thickness, as described above, an etching amount in the lateral direction can be reduced, and a pattern interval can be reduce. That is, a control IC requiring a fine pattern can be mounted. Though these conductive patterns are roughly illustrated due to space limitations on paper, the control IC has approximately 20 to 100 pins or more, and the pad on the front surface of the mounting board connected to a pad electrode on the IC side and the wiring integrated therewith can be patterned with a small lines and spaces and high density due to the small film thickness. Then, due to the resistance of the thin conductive pattern, it is not preferable to pass a high current through this thin conductive pattern. Thus, the via 72 is provided in the portions 62 and 64 corresponding to pads or electrodes where the high current flows in (or out), and since a conductive material is filled in this via, the resistance is extremely small. Thus, as illustrated by a bold arrow in FIG. 1B, the high current flows to the back surface electrode through the via 72, and this via 72 is electrically connected to an electrode of a set board provided corresponding to the back surface electrode, thereby passing the current to the set board side. An example of mounting on the set board (SB) is illustrated in FIG. 14A. The board includes a metal board, a glass epoxy board, a ceramic board and the like. Here, a solder is provided on the back surface of the circuit device 51 and connected to an electrode of this board (SB).

Thus, a thin two-layered circuit board is enough for the circuit board. As a result, the number of processes of manufacturing the circuit board can be decreased, thereby being able to reduce a cost, and furthermore, since the thin board is enough, there is a merit that the thickness of the insulating board can be reduced.

In order to maintain a thick Cu foil, the core layer may be made thick considering warpage. Whereas, in an embodiment of the present invention, since the Cu foil is thin, the amount of warpage is small, thereby being able to make the core layer thin. Thus, heat resistance of the insulating resin itself is high, however, the thickness can be reduced, thereby being able to reduce the heat resistance to be small. Thus, increase in temperature can be suppressed, and warpage of the board can be also suppressed. Accordingly, a large number of solder balls provided on the back surface of the mounting board is improved in flatness, and mountability onto the board (SB) is also improved.

Conductive patterns 54 and 73 on the back surface may be embedded in the insulating resin IR as in FIG. 14B.

FIG. 1 illustrates a module on which a circuit device is mounted, but may be sealed by potting, transfer molding, a case material and the like.

Subsequently, a manufacturing method will be described referring to FIG. 2.

First, as illustrated in FIG. 2A, the core layer 52 on which thin Cu foils 100 and 101 are laminated is prepared, which is referred to as a plated board 102 since Cu is covered with plating thereafter. This thin Cu foil is laminated on the core layer by plating. However, a Cu foil formed by plating in advance or a rolled Cu foil obtained by rolling a foil made of this plated film may be prepared and bonded. If the film thickness of the conductive pattern of a finished product is approximately 30 to 50 μm, since plating is applied in a process in FIG. 3, the film thickness here is obtained by subtracting such a portion therefrom. Since the flat core layer is plated or a Cu foil is formed on a separate flat surface to be a Cu foil, the Cu foils 100 and 101 on the both surfaces in FIG. 2A have flatness.

Moreover, the core layer 52 is a glass epoxy resin here, but it may be another insulating resin.

Subsequently, as illustrated in FIG. 2B, an etching resist 103 is formed on the Cu foil on the back surface side, and portions corresponding to the vias 71 and 72 are exposed by photolithography (hereinafter, the exposed portions are referred to as opening portions). Then, the Cu foil 101 on the back side is subjected to etching. Etchant is for wet use and an aqueous solution containing ferric chloride, copper chloride, and the like, for example, whereby the Cu foil on a portion corresponding to the opening portion is etched.

Subsequently, when this etching resist 103 is removed, an opening portion from which the core layer 52 is exposed is formed at a portion corresponding to the via (not shown).

Then, the back surface is irradiated with laser, thereby removing the core layer of a portion corresponding to the opening portion. Since the planar shape of the via is circular in general, the removed portion has a columnar shape or a shape expanded from the upper part like a skirt (the cross section thereof is in a trapezoid form or a shape obtained by cutting off the upper part of a cone when seen in a three-dimensional manner). As illustrated in FIG. 2C, in general, the copper foil on the front surface remains as it is, while only the portions of the via on the back surface are opened, and the back surface of the Cu foil 100 on the front surface is exposed. Here, each of the portions is referred to as a hole H.

Moreover, in place of FIG. 2C, the Cu foil 100 on the front surface may be patterned during etching of the opening portion in FIG. 2D. The holes Hare removed by laser as described above.

Subsequently, a process in FIG. 3 will be described. This is a process of forming plated films 105 and 106 by a plating method for patterning. First, as illustrated in FIG. 3A, the hole H is filled, and the vias 71 and 72 are formed using the plating method. Here, non-electrolytic plating, and thereafter, electrolytic plating are performed. Since the non-electrolytic plating has no selectivity in film formation area, the entire areas on the front surface and the back surface are plated. Subsequently, the electrolytic plated film is formed on this non-electrolytic plated film, resulting in both films formed on the entire surfaces. In FIG. 3A, the vias 71 and 72 are completely filled, but the inside of the hole H may be incompletely filled. That is, it is only necessary that the sheet resistance of the Cu film attached to the side wall of the hole H is lower than the sheet resistance of the Cu film formed on the front surface, and it is not a particular problem here that vias 71 and 72 are to be completely or incompletely filled.

Subsequently, as illustrated in FIG. 3C, the Cu films on the front surface and the back surface are etched, and the first conductive pattern 53 and the second conductive pattern 54 are patterned, thereby completing the mounting board 50. Though not shown here, as described in FIGS. 1C to 1E, the solder resist is formed on the entire surfaces on the front and back, and a contact portion and a portion to be an external electrode are opened. Then, a brazing material such as a solder, a conductive paste, a conductive plated film or the like is selected, to form the opening portions.

Those having been subjected to the process in FIG. 2D proceed to FIG. 3B. Since the non-electrolytic plating, and thereafter the electrolytic plating are applied here as well, the entire surfaces both on the front and the back are formed therewith. Then, they are patterned as illustrated in FIG. 3C.

In either process, the films 100 and 101 prepared in FIG. 2A have flatness and the flatness is traced in the plated film, and thus the completed first conductive pattern 53, the third pad 62, and the fourth pad 64 are able to maintain flatness. Therefore, as illustrated in FIG. 3D, even if a metal thin line is bonded to the conductive pattern on the vias 71 and 72, the connecting strength, connecting resistance and the like are favorable.

The above description has been given for the two-layered mounting board 50, but this technical idea can be applied to the mounting board having four layers, six layers, eight layers and the like.

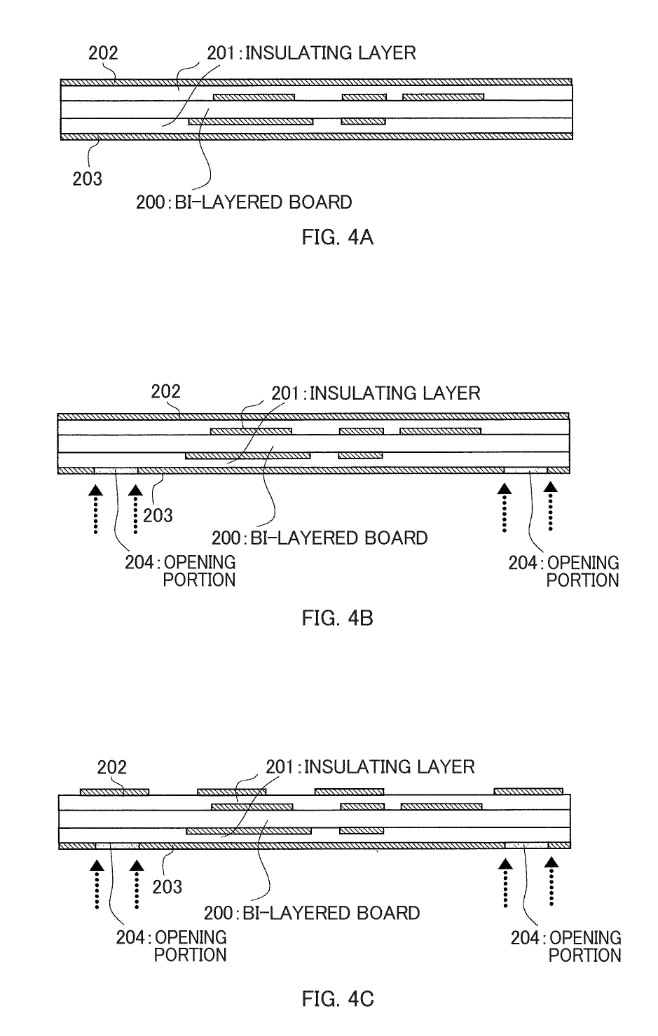

Brief description will be given below with reference to FIG. 4 using a four-layered board as an example.

First, as illustrated in FIG. 4A, Cu foils 202 and 203 are formed on the front and back surfaces of a two-layered board 200 through an insulating layer 201 using the plating method, or the Cu foils are prepared and bonded in advance.

Subsequently, as illustrated in FIG. 4B, a portion of the Cu foil corresponding to the via on the back surface is etched such that an opening portion 204 is formed, and the insulating layer and the core layer at the portion of the via are removed by laser.

Alternatively, as illustrated in FIG. 4C, when the Cu foil at the portion corresponding to the via is etched, the Cu foil on the front may be etched, and thereafter the insulating layer and the core layer at the portion of the via may be removed by laser.

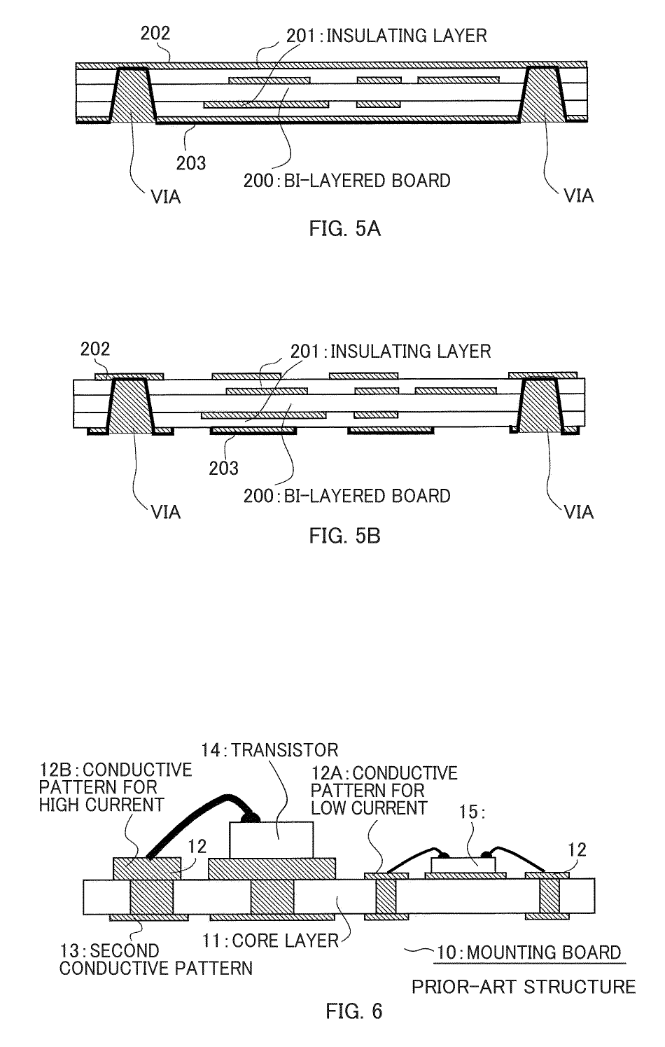

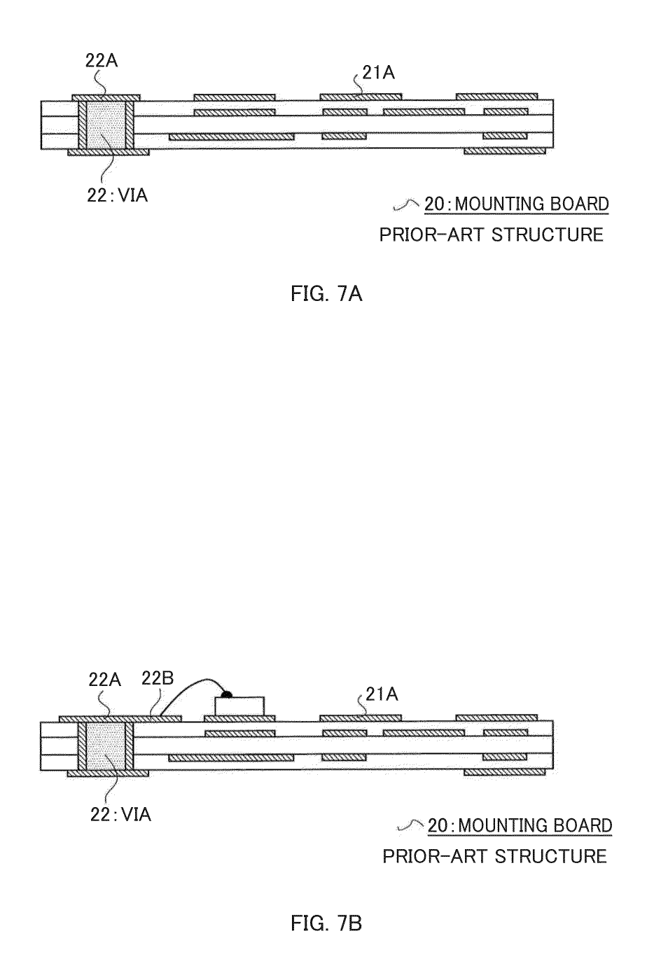

Thereafter, in both the processes, the non-electrolytic plating and electrolytic plating are applied on the front and back surfaces including the via. In order to obtain the result as illustrated in FIG. 5B, only patterning the front and back surfaces is necessary in FIG. 4B after the above processes.

In the case of FIG. 4C as well, since the plated film grows on the entire area, patterning is performed by etching and completed as in FIG. 5B. Thereafter, the solder resist is subjected to the processing similarly to the explanation on the two-layered board.

Since the mounting board 50 in FIG. 1 employs a thin film thickness, the electrode 62 or 64 for a high current on the front surface is connected to the conductive pattern on the back surface corresponding thereto through the via 72. Then, the current flows from the via 72 through the electrode on the back surface and is connected to the electrode of the set board.

The boards illustrated in FIGS. 1 and 5 are bonded to a second mounting board as illustrated in FIGS. 8 and 9. The second mounting board includes a metal board, a printed board, or a ceramic board, and is bonded onto the surface at least partially. The back surface of the mounting board is electrically connected to the electrode provided on the second mounting board. Moreover, as illustrated in FIG. 9, it may be bonded onto an island of a lead frame at least partially.

Such a configuration will be made clear in the explanation below. A following embodiment is substantially the same as above except that the electrode on the back side of the mounting board is thick.

As described above, the example in which the back-surface electrode is thick will be described below. In the above-described configuration, it is difficult for the high current of the electrode 73 on the back surface to be passed from this position to another by wiring. That is because the thickness is small and there is resistance. Thus, if a high current is to be passed to another area, a thick wiring is provided on the set board, thereby being able to pass the current by the wiring.

Thus, FIGS. 8 and 9 illustrate a case in which the conductive pattern on the back surface is formed to be great in film thickness. With the conductive pattern on the back surface having a great thickness as such, a high current can be passed through this wiring.

In FIG. 8, a two-layered board or particularly a two-layered board having a thin front surface and a thick back surface is bonded to a metal board 300. Here, in an area where the circuit device 51 is mounted, a conductive pattern is not provided on the metal board 300. However, as illustrated in FIG. 14B, an electrode and a conductive pattern may be provided on the metal board 300 and electrically connected.

This metal board 300 is mainly made of Al or Cu. In the case of Al, if the surface is oxidatively-treated, corrosion resistance and insulation properties thereof become excellent, but this oxidized film may be omitted. This two-layered mounting board is bonded by an insulating resin IR. Here, thick conductive patterns 54 and 73 on the back surface are embedded in the insulating resin. This insulating resin may be such that there is an insulating resin on the metal board side and the insulating resin IR for embedding is provided thereon.

In FIG. 8B, a dotted line indicates an electrode on the back side of the core layer 52. As in the case with reference numeral 301, the thick second conductive patterns 54 and 73 have functions of an electrode and wiring. They also have a function of a heat sink. The high current flowing from the power transistor 55B flows to the thick second conductive pattern on the back side through the thick wire 75. Since a process of roughening the surface is not applied to the portion immediately above the via and the surface is flat, favorable connection is conductive pattern 301 on the back through a pattern which is to be wiring, and flows to the end of the mounting board 50 located in the vicinity of a metal board side surface 302. Here, a via is provided in the core layer 52 and is electrically connected to a first conductive pattern L on the front surface side. Thus, the current flows again to the front surface side to the lead connection pad L.

By configuring as such, an external lead can be connected to the lead connection pad L in the vicinity of the side surface 302 of the metal board 300 as necessary.

Though not shown, this metal board and the mounting board 50 may be sealed by the insulating resin using a transfer mold. They may be covered with the insulating resin including the back surface of the metal board, or the back surface of the metal board may be exposed. Moreover, they may be sealed with a case material, can or the like.

Hereinabove, the thick conductive pattern on the back side may have a function of wiring on the back surface side of the mounting board unlike the configuration in FIG. 1. Thus, flexibility in circuit configuration is increased. Moreover, since the second conductive pattern has a large thickness, it functions as a heat sink, and the heat is transmitted to the metal board.

As described above, a printed board or a ceramic board may be used in place of the metal board.

FIG. 9 illustrates an example in which the mounting board 50 is bonded to an island of a lead frame usually employed for a semiconductor in place of the metal board. Here, SIP is illustrated, but any package with an island indicated as DIP, QFP, QFN and the like may be used. A lead 601 is prepared as a lead frame together with an island, and one end thereof is located in the vicinity of the island 600. Thus, similarly to an embodiment described above, the second conductive pattern on the back surface can be routed to the mounting board 50 located in the vicinity of the side surface of the island 600.

Since a wire-bonding point, that is, the point immediately above the via 72 is flat, it realizes favorable connection. The current is passed through this via 72 and flows to the second conductive pattern 54 on the back. Then, the current is passed from the electrode 73 on the back surface through a pattern which is to be wiring, and flows to the vicinity of the side surface 602 of the island 600. Here, the via is provided in the core layer 52, and the current flows to the first conductive pattern on the front surface side. Here, since the lead connection pad L and the via are connected to each other, the current flows again to the front surface side and flows to the connected lead.

By configuring as above, the lead and the lead connection pad can be connected using a metal thin line in the vicinity of the side surface of the island 600 (periphery of the mounting board 50). The thick solid line on the outside is an insulating resin for sealing, and seals the island and a circuit device and the like mounted thereon.

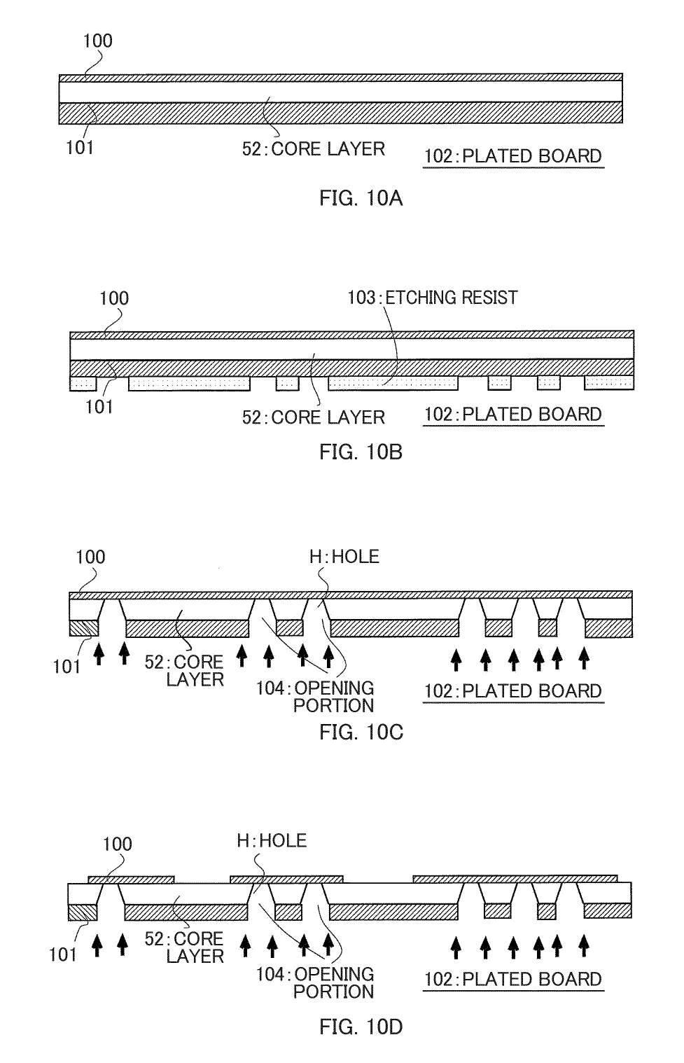

Referring FIG. 10, a manufacturing method of the circuit device 51 to be mounted will be described.

FIG. 10A illustrates that a Cu foils are bonded to the both surfaces of the core layer 52 made of an insulating resin. The Cu foil 101 on the back surface side is formed to be thicker than the Cu foil 100 on the front surface side. This is, as described above, to ensure a passage and wiring for a high current on the back surface of the mounting board. These Cu foils may be formed into a film by plating, or a Cu foil may be prepared and bonded together in advance.

Subsequently, an opening portion 104 which is to be a via is formed. In FIG. 10B, the back surface is covered with an etching resist 103 so that a portion corresponding to the via is exposed. Thereafter, the Cu foil 101 on the back surface is etched using this resist as a mask. The core layer 52 is exposed in this etched portion and will be a laser irradiated portion afterward.

Subsequently, as illustrated in FIGS. 10C and 10D, the insulating resin is removed by laser. FIG. 10C illustrates that laser irradiation is to be performed in a state where the Cu foil 100 on the front surface is not patterned, while FIG. 10D illustrates that laser irradiation is to be performed after the Cu foil 100 on the front surface is patterned. At this time, a via is formed also in a portion of the lead fixing pad L.

The patterning on the front surface is either performed at the same time as patterning of the vias in FIG. 10B or before or after the process.

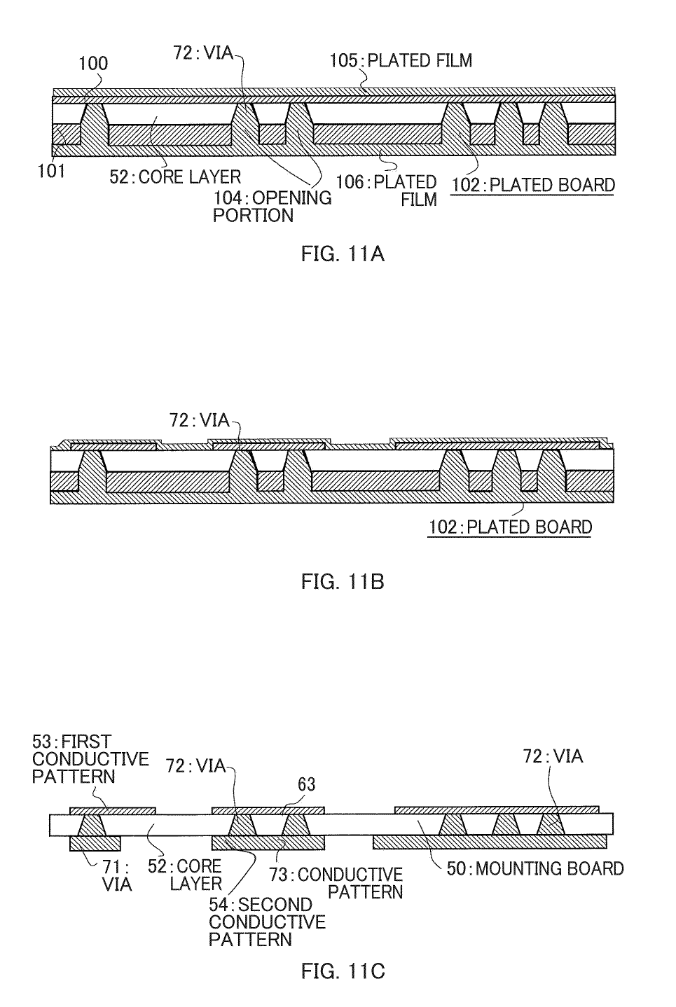

Subsequently, FIG. 11 will be described. FIG. 10C corresponds to FIG. 11A, and FIG. 10D corresponds to FIG. 11B.

This process includes various works such as plating, solder embedding, conductive paste embedding and the like. Here, Cu is embedded by plating in the opening portion 104. Since the insulating resin is exposed in an inner wall of the via, a conductive material is formed into a film and embedded by non-electrolytic plating, followed by electrolytic plating. The Cu plating is employed here, but such a material is selected that can be formed into a film by plating such as Au plating.

Subsequently, as illustrated in FIG. 11C, the Cu foils on the front and back are patterned. Here, the both surfaces may be etched back on the entire surfaces without using a resist. Alternatively, it may be so configured that an etching resist is formed, the resist on a separation portion is removed, and patterning is performed by wet etching. The front surface and the back surface may be worked at the same time or may be etched separately.

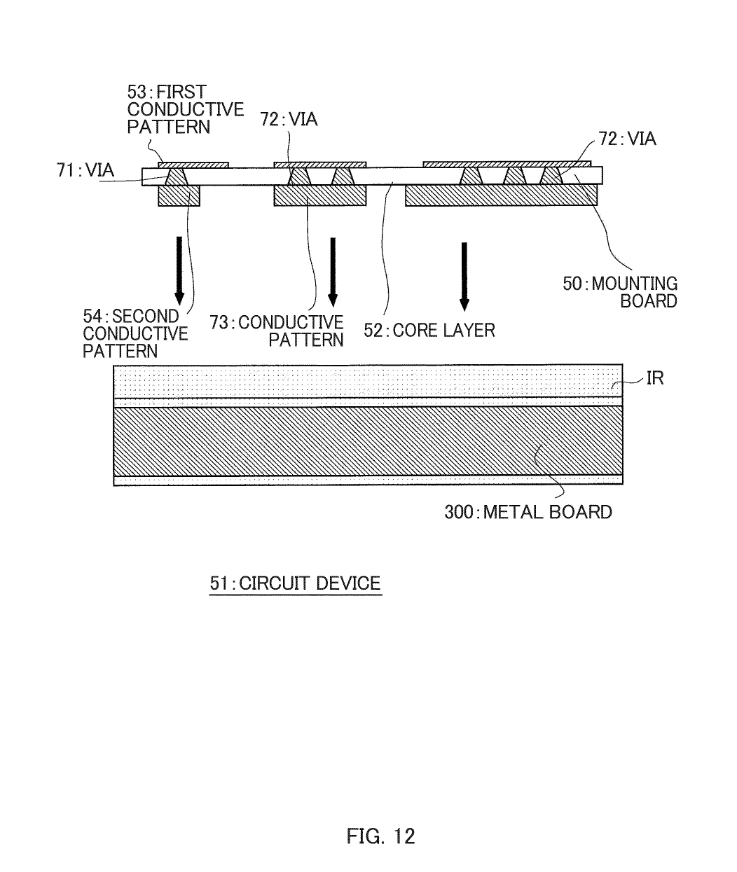

Subsequently, as illustrated in FIG. 12, a process of bonding to a metal board is performed.

Here, the insulating resin IR before being cured is provided on the metal board 300 side, and the mounting board 50 is embedded when the resin IR is in a heated and softened state. Thereafter, the resin is cured by application of heat.

To the contrary, an adhesive is applied onto the mounting board 50 side or an adhesive made of a sheet-shaped insulating resin is provided and thermally pressure-bonded to the metal board 300. Thus, the thick conductive pattern on the mounting board 50 side is embedded in the insulating resin IR provided between the metal board and the mounting board.

Though not shown, devices are mounted and electrically connected as illustrated in FIG. 8.

By making configuration as such, this board module can handle a low current and a small signal with the thin conductive pattern on the front surface and a high current and a large signal with the thick conductive pattern on the back surface. Moreover, since the wiring for a high current is provided between the metal board and the mounting board, a signal for a high current and a large signal can be re-wired on the back surface side as in the portion of the lead pad in FIG. 8B, and taken out to the front surface side in the vicinity of the outer periphery (side) of the metal board.

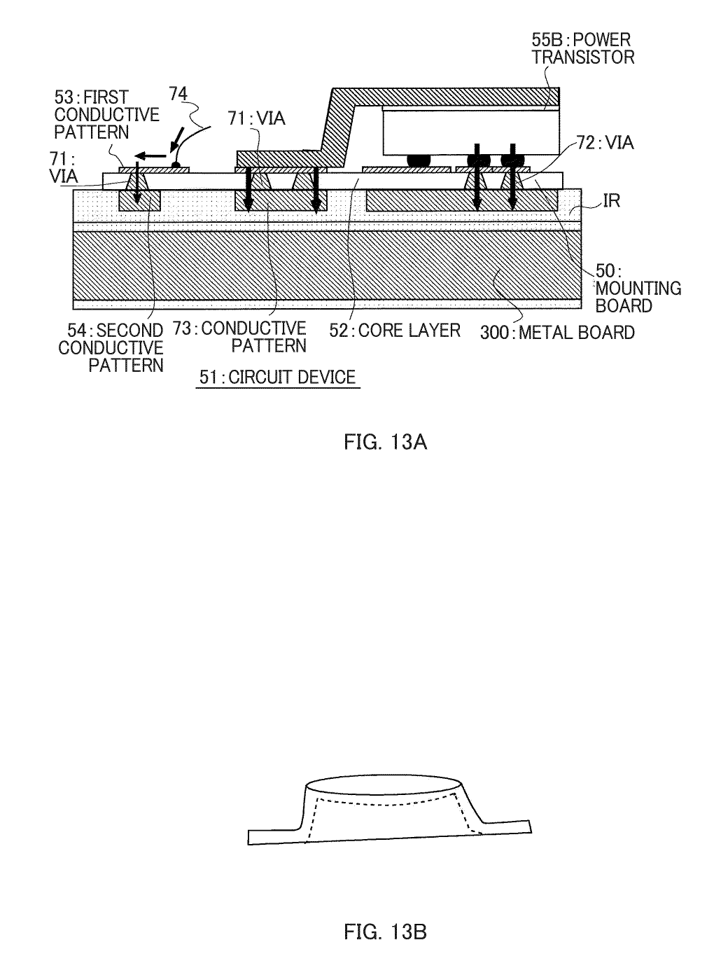

FIG. 13 illustrates face-down mounting of a semiconductor device when a device is mounted after FIG. 12. In the case of the power transistor 55B, a metal plate is provided on the back surface of a chip, and the chip back surface and the electrode of the mounting board are electrically connected.

The electrode may be a can type instead of the plate as illustrated in FIG. 13B. The chip back surface may be fixed on the back side of the upper face, and such an electrode may be also used that a side surface extends downward from the periphery of the upper surface in the cylindrical or box shape and horizontally extends in the shape of a flange on the lower side.

In this case, a via is provided anywhere corresponding to the flange-shaped electrode, and a channel can be expanded unlike a plate, which is suitable for a high current.

The chip back surface is a drain or a source, and a part having a via of the chip front surface is a source or a drain and a part without a via thereof is a gate. Moreover, an IC, in place of the power transistor, may be face-down mounted.

In the case of FIG. 13, sealing may be performed by transfer molding.

Moreover, in FIG. 12, a conductive pattern such as an electrode and/or wiring is not formed on the metal board 300 side. Bonding maybe performed such that at least a region thereof where the mounting board 50 is to be bonded is brought close to the metal board with a conductive pattern omitted, or as illustrated in FIG. 14B, a conductive pattern may be provided on a portion requiring electrical connection, and this may be bonded to the mounting board 50 and electrically connected.

According to an embodiment of the present invention, the pad 64 for a high current is formed having a small film thickness, but the via 72 having a low resistance value is provided below that. Thus, the current flows to the back surface through the via 72 brought into contact with the pad 64 without fail, and does not flow to the first conductive pattern side on the front side. Therefore, it is only necessary to draw the first conductive pattern mainly for a low current. As a result, the film thickness of the first conductive pattern can be reduced, a fine pattern can be drawn, and etching can be completed in a single process, thereby being able to reduce a cost. Moreover, as illustrated in FIG. 8, since the conductive pattern 73 on the back surface is formed thick and configured including the wiring, a passage for the high current can be extended to an arbitrary portion on the back surface. Thus, a high current can be passed to the pad on the front side connected to the lead or a large signal can be taken out through the via 71.

The above-described embodiment of the invention is for facilitating understanding of the present invention and should not be interpreted to limit the present invention. The present invention can be changed or improved without departing from the gist thereof, and the present invention includes its equivalents.

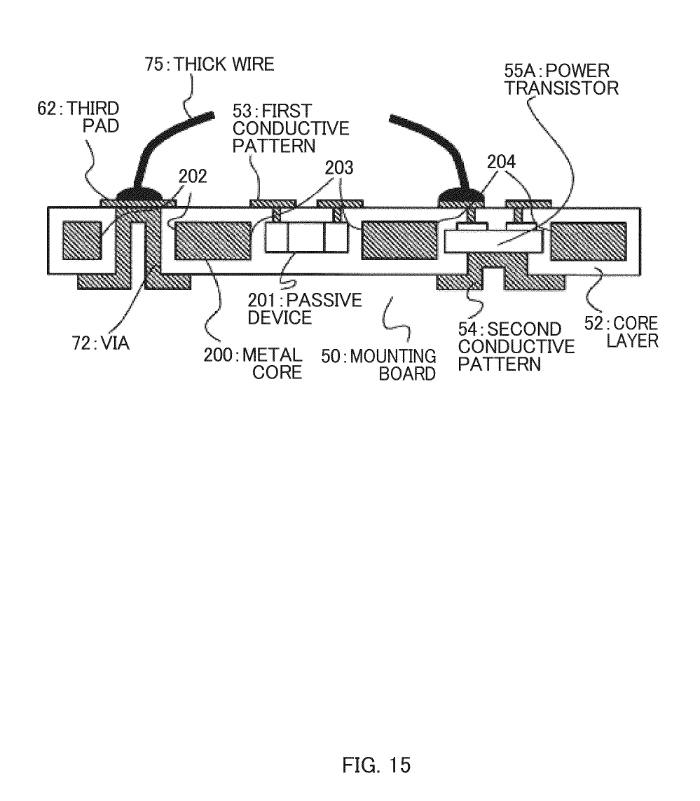

FIG. 15 describes a further example application, where a passive device or an active device is incorporated in the mounting board in FIG. 1, and except for this, the essential features are assumed to be the same as those of the present invention. The present configuration is generally called an embedded board. The components similar to those in FIG. 1 are given the same reference numerals as much as possible.

A great difference between this mounting board 50 and that in FIG. 1 is that a metal core 200 is inserted into the core layer 52. A sheet of metal core 200 has a portion 202 corresponding to the via 72, and embedded portions 203, 204 and the like, which are opened in a land state, and this metal core is sandwiched by insulating resins constituting the core layer 52.

The first opening 202, in consideration of short-circuit with an electrode material filled in the via 72, has the core layer 52 located so as to cover the inside of the first opening, and the opening 202 has a size slightly larger than the via 72.

The second opening 203 is an area in which a passive device 201 is incorporated and has a size slightly larger than this passive device. The same applies to the third opening 204. Here, the power transistor 55A is incorporated, and the opening is provided having a size slightly larger than this transistor. Here, the component referred to as reference numeral 55A only needs to be a semiconductor device or may be an IC. This is of such a type that the board back side is in contact with the second conductive pattern and is a power semiconductor device in which a current flows from and/or into the board back surface thereof.

The metal core 200 in which the passive device 201 and the semiconductor device 55A are accommodated in the openings thereof is covered with the insulating resin 52 which is the core layer 52 from the front surface and the back surface. Since fluidity is given by heating, the insulating resin extends to an unfilled part in the opening portion.

Here, by bonding an insulating resin sheet with a copper foil on the front side, a board bonded with a flat copper foil only on the front surface can be prepared. Then, an electrode portion of the semiconductor device 55A is selectively opened, plating is filled therein, and patterning is performed, thereby enabling a thin and fine pattern only on the front surface.

The portions of the via 72 and/or the back surface of the semiconductor device are opened by laser or mechanical working from the back, thereby exposing the back surface of the third pad 62. Moreover, the back surface of the semiconductor chip is exposed.

Then, these openings are filled with plating, a brazing material, a conductive paste or the like from the back surface. Here, since the thickness is greater only by the portion of the metal core 200, the via is not completely filled. In short, it is only necessary that plating is thicker than the first conductive pattern and the via portion has a resistance value smaller than that of a portion extending from the third pad to the wiring.

By configuring as above, heat of the semiconductor device 55A flows to the metal core of the mounting board and the back side, and if being mounted on a metal board, etc., favorable heat radiating performances can be maintained.

Further, the mounting board 50 may include a ceramic board.

Furthermore, in an embodiment according to the present invention, a metal board (one on which a mounting board according to an embodiment of the present invention is mounted) is described using the metal board (FIG. 8) and the metal island (FIG. 9), however, when the mounting board 50 in FIG. 1 is a board made of ceramic, which is more excellent in heat radiating performance than a mounting board made of resin, a resin board may be used in place of the metal board (FIG. 8).

What is claimed is:

1. A mounting board comprising:
a core layer made of an insulating resin;
a first conductive pattern provided on a front side of the core layer;
a second conductive pattern provided on a back side of the core layer; and
a via provided between a first electrode for a high current in the first conductive pattern and an external electrode including the second conductive pattern, the external electrode provided so as to correspond to the first electrode,
the first conductive pattern and the second conductive pattern having the same film thickness,
the via set at a resistance value lower than a resistance value of the first conductive pattern so that the high current flows to the external electrode through the via.

2. The mounting board according to claim 1, wherein
the via is opened from a core layer side toward the first electrode, and
the first electrode corresponding to the via is substantially flat.

3. The mounting board according to claim 2, wherein
the first conductive pattern includes a first island provided with a first circuit device configured to pass a high current, a second island provided with a second circuit device configured to pass a low current, and the first electrode provided in the vicinity of the first island.

4. A mounting board comprising:
a core layer made of an insulating resin;
a first conductive pattern including at least a first island, a second island, a first electrode, a second electrode and wiring, the first conductive pattern provided on a front side of the core layer;
a second conductive pattern being an external electrode, the second conductive pattern provided on a back side of the core layer; and
a via provided between the first electrode and the external electrode provided so as to correspond to the first electrode,
the first conductive pattern and the second conductive pattern having the same film thickness,
the via is set at a resistance value lower than a resistance value of the first conductive pattern so that a current flowing from a power transistor, which is to be mounted on the first island, or a current flowing into the power transistor flows to the external electrode through the via.

5. The mounting board according to claim 4, wherein
the via is opened, by means of laser, from a core layer side toward the first electrode, and
the first electrode corresponding to the via is substantially flat.

6. A circuit device comprising
the mounting board according to claim 1 mounted on a metal board, a printed board made of an insulating resin, or a ceramic board.

7. A circuit device comprising
the mounting board according to claim 4 mounted on a metal board, a printed board made of an insulating resin, or a ceramic board.

8. A circuit device comprising:
an island; and
a lead having at least one end thereof close to outer periphery of the island,
the island provided with the mounting board according to claim 1.

9. A circuit device comprising:
an island; and
a lead having at least one end thereof close to outer periphery of the island,
the island provided with the mounting board according to claim 4.

10. A mounting board comprising:
a core layer made of an insulating resin;
a first conductive pattern provided on a front side of the core layer;
a second conductive pattern having a film thickness greater than a film thickness of the first conductive pattern, the second conductive pattern provided on a back side of the core layer;
a first electrode for a high current including at least one of the first conductive patterns;
an external electrode including at least one of the second conductive patterns, the external electrode provided so as to correspond to the first electrode; and
a via provided between the first electrode and the external electrode,
the via is set at a resistance value lower than a resistance value of the first conductive pattern so that the high current flows to the external electrode through the via.

11. The mounting board according to claim 10, wherein
wiring in the second conductive pattern integral with the external electrode is extended to a position different from that of the external electrode.

12. The mounting board according to claim 10, wherein
wiring in the second conductive pattern integral with the external electrode is extended to a first area in the vicinity of a side of the mounting board or in the vicinity of outer periphery thereof and the wiring is electrically connected to a pad electrode in the first conductive pattern through the via in the first area.

13. A circuit device comprising
the mounting board according to claim 10 mounted on a metal board, a printed board made of an insulating resin, or a ceramic board.

14. A circuit device comprising
the pad electrode including the mounting board according to claim 12 provided with a lead.

15. A circuit device comprising
the mounting board according to claim 12 including an island and a lead having one end provided close to periphery of the island, the mounting board fixed to the island, the lead electrically connected to the pad electrode.
